(19) United States
(12) Patent Application Publication
(10) Pub. No.: US 2013/0076078 A1
(43) Pub. Date: Mar. 28, 2013

(54) SUNROOF PANEL WITH SOLAR CHARGING SYSTEM FOR A MOTOR VEHICLE

(71) Applicant: Pradeep RAMDEO, Bronx, NY (US)

(72) Inventor: Pradeep RAMDEO, Bronx, NY (US)

(21) Appl. No.: 13/327,912

(22) Filed: Dec. 16, 2011

Related U.S. Application Data
(60) Provisional application No. 61/538,858, filed on Sep. 24, 2011.

(51) Int. Cl. B60J 7/043; H01L 31/048

(52) U.S. Cl. 296/216.01; 136/251

(57) ABSTRACT

A sunroof panel is provided with a solar charging system for a motor vehicle which includes a solar panel sunroof installed in an opening in a roof of the motor vehicle to convert solar energy from the sun into electrical energy and send the electrical energy to a battery in the motor vehicle. The system has 12-24 VDC and charge level indicator. The electronic equipment within the motor vehicle is electrically connected to the battery to receive supplemental power in order to be utilized by a driver of the motor vehicle.

### CROSS-REFERENCE TO RELATED APPLICATION

This application claims the benefit of Provisional Patent Application No. 61/538,858, filed on Sep. 24, 2011, in the United States Patent & Trademark Office, the disclosure of which is incorporated herein by reference.

### BACKGROUND OF THE INVENTION

1. Field of the Invention

The present invention relates to a solar collection device, and more particularly, a solar charging system for a motor vehicle.

Many drivers choose to drive an electric or hybrid motor vehicle in order to reduce emissions of carbon dioxide. However, the current electric motor vehicle must be frequently recharged at a charging station. Drivers often forget to charge the battery, which can lead to a loss of power while on the road. Many drivers would find it convenient if they could charge the electric motor vehicle while driving or while parked outside. Using the sun as an energy source would be an ideal electricity charging alternative.

The solar charging system consists of a vehicle sunroof that utilizes a pre-installed solar panel to generate power. The present invention can assist in producing energy in order to power electric/hybrid motor vehicles. It can also be used in conjunction with gas-powered motor vehicles to provide supplemental power in order to operate an audio/video player, a laptop computer, a portable vacuum cleaner, a cell phone charger, a navigation device and other electronic equipment. Using the solar charging system to produce additional energy eliminates the need to constantly plug in the electric motor vehicle for recharging. The present invention provides convenience and practicality to all drivers.

2. Description of the Prior Art

Numerous innovations for vehicle solar panels have been provided in the prior art that will be described. Even though these innovations may be suitable for the specific individual purposes to which they address, however, they differ from the present invention.

A FIRST EXAMPLE, U.S. Pat. No. 4,911,257, Issued on Mar. 27, 1990, to Kajimoto et al. teaches a solar battery system for a vehicle that comprises a solar battery mounted on a body of the vehicle, an actinometer provided on the body for detecting the quantity of solar radiation supplied to the body, a controller for comparing an output of the solar battery with a detection output of the actinometer to obtain a result of comparison and generating an alarm signal when the result of comparison is out of a predetermined condition, and a warning device provided in a cabin formed in the vehicle for giving a warning in response to the alarm signal obtained from the controller.

A SECOND EXAMPLE, U.S. Pat. No. 5,089,764, Issued on Feb. 18, 1992, to Bobier et al. teaches an apparatus and system for purging hot air from the cabin of vehicles when parked under hot sun conditions. The system employs a solar panel of relatively smaller size suited for incorporation with a sun roof or rear window of the vehicle. A power transfer regulator is utilized which is responsive to the peak voltage characteristic of the solar panel to cause the panel to substantially continuously to perform at its peak power output capability. As such, an equivalent power at lower voltage and enhanced current levels is submitted to the electric drive motor of an air purging fan within the vehicle. Switching controls are provided which monitor the state of the vehicle's internal combustion engine through its ignition switch and which provide turn-on of the purging system at such time as vehicle cabin temperatures reach predetermined levels. When the air circulation system is disabled, the solar panel is employed for charging the battery of the vehicle.

A THIRD EXAMPLE, U.S. Pat. No. 5,288,925, Issued on Jul. 20, 1993, to Nath et al. teaches a photovoltaic window assembly suitable for use in building and vehicular applications. The window assembly includes an optically-transmissive substrate having one or more photovoltaic devices disposed thereon. A decorative template having cut-outs coextensive with each of the photovoltaic devices is disposed on the substrate such that the photovoltaic devices extend through the cut-outs. A window opening is also formed in the decorative template for transmission of light. An encapsulating layer is formed on the substrate, solar cells and decorative template to protect the solar cells and assembly from environmental damage and deterioration.

A FOURTH EXAMPLE, U.S. Pat. No. 6,406,090, issued on Jun. 18, 2002, to Tolinski et al. teaches a self-powered sunroof assembly that can be mounted in the roof of a vehicle and includes a movable panel, preferably a window, a motor for controlling movement of the movable panel, and a self-contained power supply unit that supplies power to the motor. The self-contained power supply unit contains a battery and at least one solar cell array that charges the battery. The solar cell array is preferably attached to the movable panel but may be located anywhere on the sunroof assembly that may be directly or indirectly exposed to sunlight. Additionally, placement of the solar cell array on the movable window does not decrease visibility through the window.

A FIFTH EXAMPLE, U.S. Pat. No. 6,682,132, issued on Jan. 27, 2004, to Hahn teaches a roof module for a motor vehicle and a process of producing a roof module which includes at least two flat roof covers located adjacent to one another and which are joined to one another using a tool which disperses a peripheral foam material.

A SIXTH EXAMPLE, U.S. Patent Office Publication No. 2005/0046241, Published on Mar. 3, 2005, to Sasaki et al. teaches a sunroof apparatus which includes a sunroof panel mounted on an first opening of a roof, a sun shade provided at an inner room side of the sunroof panel, a solar cell provided to the sunroof panel and attached at one surface which is facing the sun shade for converting light energy incident from the one side surface side and the other side surface side of the sunroof panel into electric energy and a reflecting member provided to the sun shade and attached at one surface which is facing the sunroof panel.

A SEVENTH EXAMPLE, U.S. Patent Office Publication No. 2006/0156738, Published on Jul. 20, 2006, to Khalil teaches a temperature regulation system, which can be used to cool the interior temperature of an automobile/motor vehicle, when it is parked under the sun, substantially below the external temperature, was designed and produced. The system was powered by solar cells, thus functioning without dissipating any energy from the vehicle's battery. The mechanical device of the system incorporated Peltier elements, heat sinks and fans, all controlled by a power supply in the form of a circuit board. When the automobile was switched on, the system could be further used as an automobile climate control unit, for heating or cooling, withdrawing the supplementary electricity from the battery, another feature controlled by the circuit board.

AN EIGHTH EXAMPLE, U.S. Patent Office Publication No. 2007/0158978, published on Jul. 12, 2007, to Woodhouse et al. teaches a vehicle sunroof including a sunroof frame mounted to a vehicle roof opening and having opposing lateral sides. The sunroof frame has an outer edge adjacent to the outer surface of the vehicle roof and an inner edge located within the vehicle cabin. The vehicle sunroof also includes a number of solar panels. Each solar panel includes a solar collection surface for collecting sunlight for producing solar energy. The solar panels extend between and are connected to the opposing lateral sides of the sunroof frame.

A NINTH EXAMPLE, U.S. Patent Office Publication No. 2008/0100258, Published on May 1, 2008, to Ward teaches solar cells that are attached to vehicle components such as a moon roof or truck bed cover to create modular solar panels. An adjustable mount can be attached to the solar panels to adjust the angle of the solar cells in a direction of the sun. Sensing for solar tracking the sun angle can be performed using solar cells of the solar panel itself, or a separate sensor. A telescoping moon roof mount mechanism can allow a first solar panel to be extended above a vehicle roof to allow additional solar panels to be telescoped out and also exposed to the sun. An additional battery can be mounted in the truck bed cover and connected in parallel with the hybrid battery.

A TENTH EXAMPLE, U.S. Patent Office Publication No. 2010/0026235, Published on Feb. 4, 2010, to Harris teaches a charging system for a vehicle that rearranges the bank of battery cells between a series connection for delivering voltage to a load, e.g. a motor; and a parallel connection for being charged. The battery bank can thus be charged by a 12 volt battery charger. The charger can be a plug in charger, or can be a solar cell. For example, the solar cell can be moved to cover a windshield or other surface of the vehicle whenever the vehicle is shut down.

AN ELEVENTH EXAMPLE, U.S. Patent Office Publication No. 2010/0175819, published on Jul. 15, 2010, to Ryu teaches a method for manufacturing a solar cell module for a vehicle sunroof, in which a solar cell is cut into multiple pieces so that it can be closely adhered to a curved glasses of a sunroof which is generally installed at an intermediate portion of a vehicle roof so as to provide a driver with an air circulation effect in the interior of a vehicle and a fresh driving feeling with its open environment. A solar cell module for a sunroof is manufactured based on a high temperature and vacuum compression work using a laminator as an EVA film adhering unit. So, it is possible to easily perform a laminating work for adhering a sunroof curved glass and a solar cell as compared to a conventional art in which it is not easy to perform the above work.

A TWELFTH EXAMPLE, U.S. Pat. No. RE41,597, issued on Aug. 31, 2010 to Kirkpatrick teaches a system for and method for charging or maintaining a charge of a battery of a vehicle. The system utilizes a light-transforming cell that can transform light energy to current. The cell may be supported such that the cell is exposed to light energy. Current produced by the cell is communicated with the battery through electrical connectors, which may have a switch. This invention may decrease occasions when a vehicle operator faces a weakened or dead battery in a vehicle because the invention serves to maintain the charge of the vehicle's battery when the vehicle is not in use.

A THIRTEENTH EXAMPLE, U.S. Patent Office Publication No. 2011/0089887, published on Apr. 21, 2011 to Ward teaches a connection system to charge a high voltage battery in an electric vehicle with multiple low voltage solar panels (2.sub.1-n). The connection system includes sets of transmission lines to individually connect each one of the solar panels (2.sub.1-n) to each individual one of the battery cells (34.sub.1-n) making up the battery. With the connection system the high voltage battery can be charged by the lower voltage solar panels (2.sub.1-n) without using a lossy DC-DC converter system that converts the DC solar panel output to AC for transforming to the much higher voltage across the primary terminals of battery before converting back to DC to connect to the battery.

It is apparent now that numerous innovations for vehicle solar panels have been provided in the prior art that are adequate for various purposes. Furthermore, even though these innovations may be suitable for the specific individual purposes to which they address, accordingly, they would not be suitable for the purposes of the present invention as heretofore described.

### SUMMARY OF THE INVENTION

AN OBJECT of the present invention is to provide a solar charging system for a motor vehicle that avoids the disadvantages of the prior art.

ANOTHER OBJECT of the present invention is to provide a solar charging system for a motor vehicle that is simple and inexpensive to manufacture.

STILL ANOTHER OBJECT of the present invention is to provide a solar charging system for a motor vehicle that is simple to use. BRIEFLY STATED, STILL YET ANOTHER OBJECT of the present invention is to provide a solar charging system for a motor vehicle which comprises a solar panel sunroof installed in an opening in a roof of the motor vehicle to convert solar energy from the sun into electrical energy and send the electrical energy to a battery in the motor vehicle. Electronic equipment within the motor vehicle is electrically connected to the battery to receive supplemental power in order to be utilized by a driver of the motor vehicle.

The novel features which are considered characteristic of the present invention are set forth in the appended claims. The invention itself, however, both as to its construction and its method of operation, together with additional objects and advantages thereof, will be best understood from the following description of the specific embodiments when read and understood in connection with the accompanying drawing.

### BRIEF DESCRIPTION OF THE DRAWING

The figures of the drawings are briefly described as follows:

FIG. 1 is a block diagram showing the various components of the present invention;

FIG. 2 is a perspective view of a motor vehicle showing the solar panel sunroof installed in an opening in a roof of the motor vehicle; and

FIG. 3 is a perspective view of the interior of the motor vehicle showing electronic equipment being powered by the solar panel sunroof.

### REFERENCE NUMERALS UTILIZED IN THE DRAWING

110 solar charging system
112 motor vehicle
114 solar panel sunroof of system 110
116 opening in roof 118
118 roof of motor vehicle 112
120 solar energy from sun 122
122 sun
124 electrical energy from solar panel sunroof 114
126 battery in motor vehicle 112
128 electronic equipment in motor vehicle 112
130 driver of motor vehicle 112
132 frame of solar panel sunroof 114
134 transparent glass plate of solar panel sunroof 114
136 photovoltaic solar cells of solar panel sunroof 114
138 12VDC-24VDC converter/regulator of solar panel sunroof 114
140 charge level indicator of solar panel sunroof 114
142 cell phone charger for electronic equipment 128
144 navigation device for electronic equipment 128
146 audio/video player for electronic equipment 128

### DETAILED DESCRIPTION OF THE PREFERRED EMBODIMENT

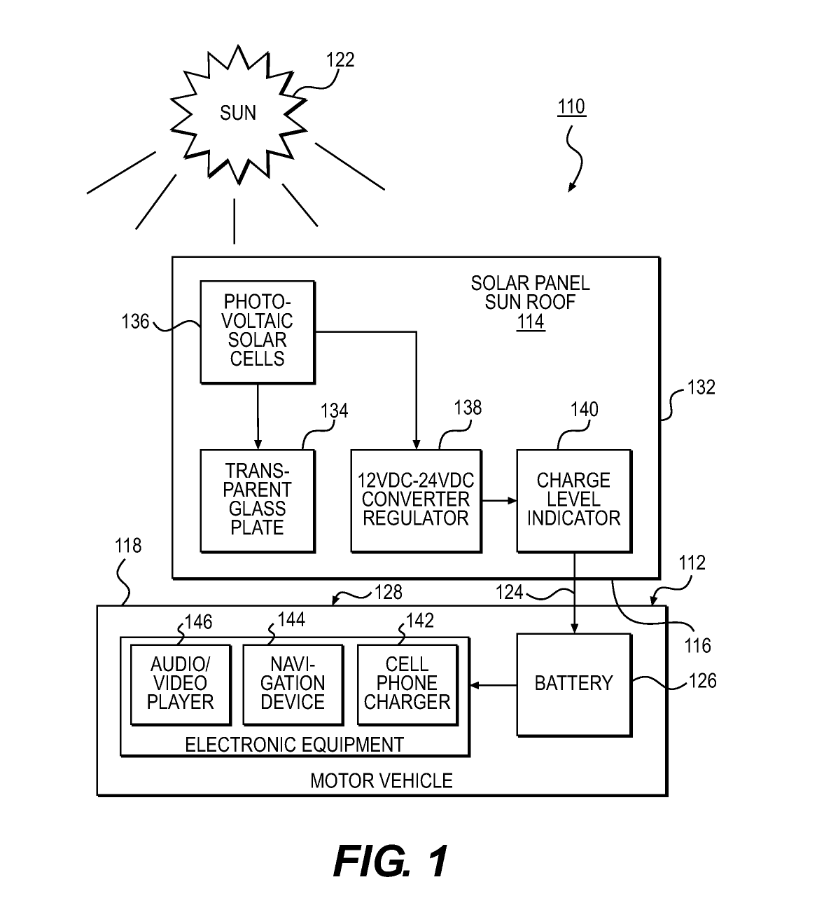

As shown in FIG. 1, the present invention is a solar charging system 110 for a motor vehicle 112 which comprises a solar panel sunroof 114 installed in an opening 116 in a roof 118 of the motor vehicle 112 to convert solar energy 120 from the sun 122 into electrical energy 124 and send the electrical energy 124 to a battery 126 in the motor vehicle 112. Electronic equipment 128 within the motor vehicle 112 is electrically connected to the battery 126 to receive supplemental power in order to be utilized by a driver 130 of the motor vehicle 112.

The solar panel sunroof 114 comprises a frame 132. A transparent glass plate 134 is mounted in the frame 132. A plurality of photovoltaic solar cells 136 are positioned in series on the transparent glass plate 134. The solar panel sunroof 114 further comprises a 12VDC-24VDC converter/regulator 138 and a charge level indicator 140.

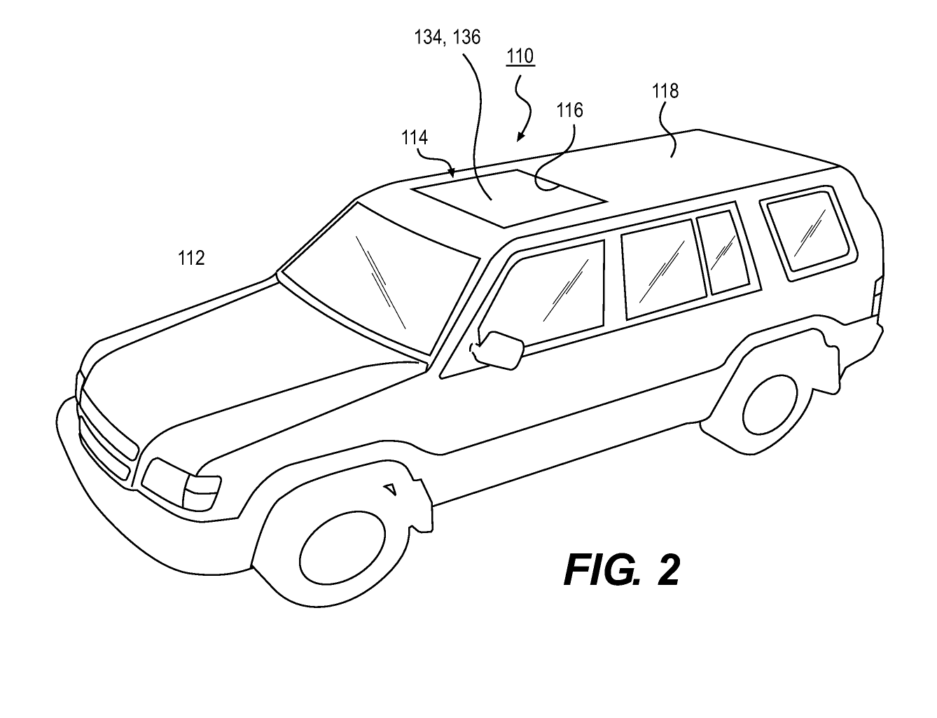

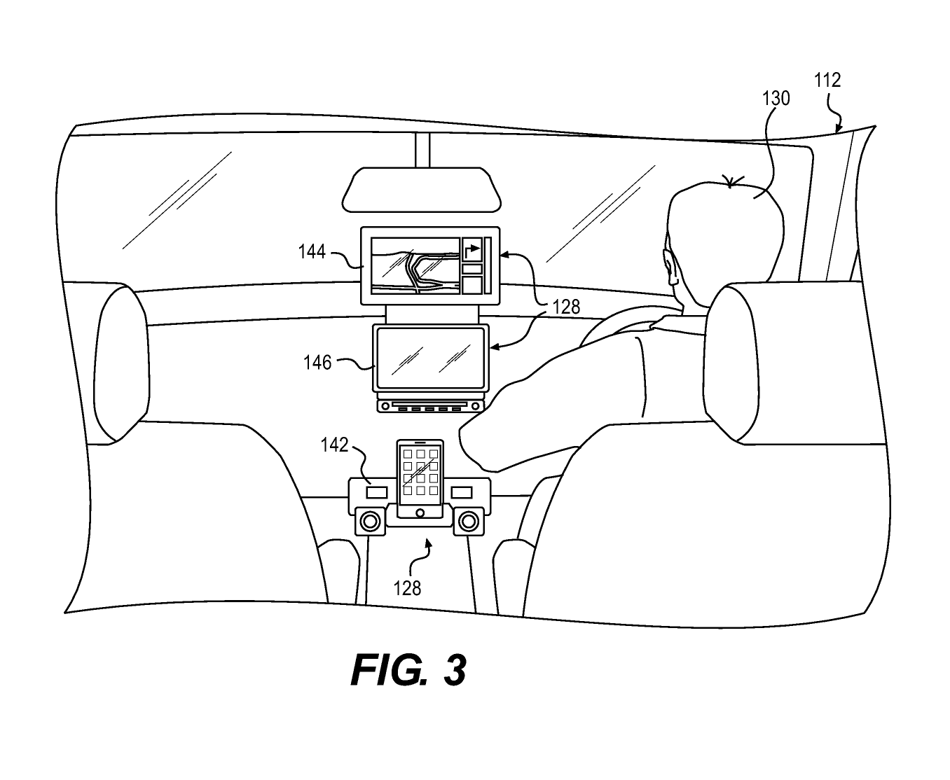

FIG. 2 shows the solar panel sunroof 114 in the opening 116 in the roof 118 of the motor vehicle 112. FIG. 3 shows the interior of the motor vehicle 112 with the electronic equipment 128 consisting of a cell phone charger 142, a navigation device 144 and an audio/video player 146.

The solar panel sunroof 114 may be manually operated or motor driven, and is available in many shapes, sizes and styles. The solar panel sunroof 114 actually includes a transparent glass plate 114 has inlaid photovoltaic solar cells 136 making the transparent glass plate 134 totally opaque. While the solar panel sunroof 114 operates identically to conventional factory-fitted glass moonroofs (tilting and retracting), the solar panel sunroof 114 can provide electricity to power interior ventilation fans, for cooling the motor vehicle interior on hot days when the motor vehicle 112 is standing outside in the sunlight. The present invention's main function is to supply electricity via the battery 126 to the electronic equipment 128. The solar panel sunroof 114 can be available as a factory option on the 2010 Prius, recent Audi cars, Renault Zoe, and also on some versions of the Mazda Millennia.

In review, the solar charging system 110 enables a driver 130 to charge a battery 126 of a motor vehicle 112 using a solar panel sunroof 114. The present invention is comprised of the solar panel sunroof 114 that is similar in appearance to conventional motor vehicle sunroofs. The solar panel sunroof 114 is installed into an opening 116 in a roof 118 of the motor vehicle 112 in a similar manner as other sunroofs and may function in much the same way. The unique feature of the solar panel sunroof 114 is that it includes a frame 132, a plurality of photovoltaic solar cells 136 in series on a transparent glass plate 134, a 12 VDC-24 VDC converter/regulator 138, and charge level indicator 140 to harness the solar energy 120 from the sun 122. The solar panel sunroof 114 may be made to be both retractable and non-retractable configurations. When closed, the solar panel sunroof 114 traps energy from the sun 122 and converts it to electrical energy 124. This power is then sent via wiring to the battery 126 and to electronic equipment 128 in the motor vehicle 112. The electronic equipment 128 can be a cell phone charger 142, a navigation device 144 and an audio/video player 146. The battery 126 can be charged while The motor vehicle 122 is driven or parked. The solar panel sunroof 114 may be available in a variety of shapes and sizes depending on the motor vehicle 112. Some solar panel sunroofs 114 may contain other materials or a combination of materials such as glass to give it an attractive look and style. The exact specifications may vary.

It will be understood that each of the elements described above, or two or more together, may also find a useful application in other types of constructions differing from the types described above.

While the invention has been illustrated and described as embodiments of a solar charging system for a motor vehicle, accordingly it is not limited to the details shown, since it will be understood that various omissions, modifications, substitutions and changes in the forms and details of the device illustrated and its operation can be made by those skilled in the art without departing in any way from the spirit of the present invention.

Without further analysis, the foregoing will so fully reveal the gist of the present invention that others can, by applying current knowledge, readily adapt it for various applications without omitting features that, from the standpoint of prior art, fairly constitute characteristics of the generic or specific aspects of this invention.

The invention claimed is:

1. A sunroof panel with a solar charging system for a motor vehicle which comprises:
a) a solar panel sunroof installed in an opening in a roof of the motor vehicle to convert solar energy from the sun into electrical energy and send the electrical energy to a battery in the motor vehicle;
b) a frame;
c a transparent glass plate mounted in the frame; and
d) a plurality of photovoltaic solar cells positioned in series on the transparent glass plate, and
e) electronic equipment within the motor vehicle electrically connected to the battery to receive supplemental power in order to be utilized by a driver of the motor vehicle.

2. The system as recited in claim 1, wherein the solar panel sunroof further comprises a 12VDC-24VDC converter/regulator.

3. The system as recited in claim 1, wherein the solar panel sunroof further comprises a charge level indicator.

4. The system as recited in claim 1, wherein the electronic equipment consists of a cell phone charger.

5. The system as recited in claim 1, wherein the electronic equipment consists of a navigation device.

6. The system as recited in claim 1, wherein the electronic equipment consists of an audio/video player.
